(19) United States
(12) Patent Application Publication
(10) Pub. No.: US 2024/0280643 A1
(43) Pub. Date: Aug. 22, 2024

(54) Method for characterizing the state of charge (SOC) of lithium-ion batteries using ultrasonic reflection coefficients

(71) Applicant: BEIJING UNIVERSITY OF TECHNOLOGY, BEIJING (CN)

(72) Inventors: Yan Lyu, BEIJING (CN); Jie Gao, BEIJING (CN); Xuan Liu, BEIJING (CN); Bin Wu, BEIJING (CN); Cunfu He, BEIJING (CN)

(21) Appl. No.: 18/650,011

(22) Filed: Apr. 29, 2024

Related U.S. Application Data
(63) Continuation of application No. PCT/CN2022/128498, filed on Oct. 31, 2022.

(30) Foreign Application Priority Data
Nov. 8, 2021 (CN) 202111315015.3

(51) Int. Cl. G01R 31/387; G01R 31/367; G01R 31/378

(52) U.S. Cl. CPC G01R 31/387; G01R 31/367; G01R 31/378

(57) ABSTRACT

The present invention discloses a method for characterizing the State of Charge (SOC) of lithium-ion batteries using an ultrasonic reflection coefficient, which employs a water immersion ultrasonic detection method for measuring the reflection coefficient angular spectrum of lithium-ion batteries. This invention pertains to the field of non-destructive testing technology. A pouch-type lithium-ion battery can be regarded as a laminated structure composed of multiple materials, and when the State of Charge (SOC) of the lithium-ion battery varies, its reflection coefficient changes accordingly. The invention acquires the reflection coefficient angular spectrum of lithium-ion batteries at different SOCs through ultrasonic water immersion detection, establishes a mapping relationship between the angular spectrum and the SOC of the lithium-ion battery, and uses the distance between the two peak values of the angular spectrum to characterize the SOC of the lithium-ion battery. The invention enables non-destructive characterization of the SOC of lithium-ion batteries and allows for localized SOC measurement of the batteries.

### CROSS-REFERENCE TO RELATED APPLICATIONS

The present application is a continuation of the international application PCT/CN2022/128498 filed on Oct. 31, 2022, which claims the priority to the Chinese Patent Application No. 202111315015.3 filed on Nov. 8, 2021. The entire contents of the above identified applications are incorporated herein by reference.

### BACKGROUND OF THE INVENTION

### 1. Technical Field

The present invention pertains to the field of ultrasonic non-destructive testing, specifically relating to a method for detecting the State of Charge (SOC) of lithium-ion batteries.

### 2. Background

Lithium-ion batteries are widely used in various fields, including aerospace, military applications, and the electric vehicle industry. However, the capacity degradation of lithium-ion batteries during charge-discharge cycles, as well as the safety performance testing, particularly the State of Charge (SOC) and State of Health (SOH), have always been focal points in the non-destructive testing of lithium-ion batteries. Lithium-ion batteries are constructed with different material layers, which complicates the propagation of ultrasonic signals. During the cycling process, the internal structure of lithium-ion batteries undergoes subtle changes, and the acoustic impedance also varies. Due to the mismatch in acoustic impedance, the reflection coefficient of ultrasonic waves will differ. This article, based on the mapping relationship between the ultrasonic reflection coefficient angular spectrum at different SOCs and the SOC of lithium-ion batteries, achieves the characterization of the SOC of lithium-ion batteries using the ultrasonic reflection coefficient angular spectrum.

### Inventive Content

In response to the aforementioned issues, the present invention designs a method for measuring the State of Charge (SOC) of lithium-ion batteries using ultrasonic detection. The technical solution of the present invention is as follows:

A method for detecting the SOC of lithium-ion batteries using an ultrasonic reflection coefficient involves the following procedural steps:

Step 1: A laminated structure pouch lithium-ion battery is discharged to a discharge cut-off voltage at room temperature using a constant current discharge device, and then allowed to rest. After resting, the pouch lithium-ion battery is charged to a charging cut-off voltage using a constant current and constant voltage charging method.

Step 2: The rested pouch lithium-ion battery is discharged to a discharge cut-off voltage at room temperature using a constant current, and N lithium-ion batteries in different states of charge are obtained based on varying discharge times. The total discharge time T is the time taken for the battery to be discharged from the charging cut-off voltage to the discharge cut-off voltage. The state of charge of the lithium-ion battery is represented by the proportion of the discharge time t. The formula for calculating the state of charge is:

$$State of Charge ( SOC ) = ( T - t ) / T * 100 \% SOC .$$

Step 3: Experimental apparatus design, to perform measurements of the ultrasonic reflection coefficient at variable angles, a measurement system for variable angle ultrasonic reflection coefficients is constructed. This measurement system includes: two ultrasonic water immersion probes (1,2), an embedded controller (3), a digital oscilloscope (4), a battery testing system (5), a middleware system (6), a water tank (7), an angular fixture (8), a lithium-ion single-cell battery specimen (9), and a computer (10). The connection method is as shown in FIG. 2. The embedded controller (3) is connected to the transmitting ultrasonic probe (1) to emit an ultrasonic wave signal. The digital oscilloscope (4) is connected to the receiving ultrasonic probe (2) and also connected to the embedded controller (3) for signal processing and data acquisition. The battery testing system (5) monitors and controls the state of charge of the lithium-ion battery in real-time, allowing for changes in the SOC of the lithium-ion battery. The computer is connected to the battery testing system via the middleware system (6) for signal transmission. The two terminals of the lithium-ion battery under test are connected to the battery testing system (5), with waterproof treatment applied to the terminals, and then immersed in the water tank (7) along with the ultrasonic probes. The two ultrasonic probes (1, 2) are secured by the angular fixture (8), and the ultrasonic signal is emitted and received at a certain angle to measure the reflected signal.

Step 4: Using an ultrasonic water immersion detection method, a lithium-ion battery at a specific state of charge obtained from Step 2 is placed into a water tank. A wideband ultrasonic probe with a certain central frequency is used to generate and receive signals, thereby capturing the ultrasonic reflection signal from the lithium-ion battery.

Step 5: Following Step 3, select the angle between the two ultrasonic probes incrementally (from 0 to 60 degrees), and capture the time-domain diagram of the ultrasonic reflection signal for each angle.

Step 6: Process the time-domain reflection signals obtained at various angles, and use Fourier transformation to derive the ultrasonic reflection coefficients of the lithium-ion battery at different angles of incidence.

Step 7: Repeat Steps 4 to 6 until the ultrasonic reflection coefficients for all states of charge (0% to 100% SOC) of the lithium-ion batteries obtained in Step 2 have been measured.

Step 8: Plot the angular spectrum of the reflection coefficients of the lithium-ion battery from 0% SOC to 100% SOC, using all the reflection coefficients obtained in Step 7.

Step 9: Analyze the changes in the positions of the two peak values in the reflection coefficient angular spectrum to establish the mapping relationship between the reflection coefficient angular spectrum and the state of charge of the lithium-ion battery, thereby characterizing the SOC of the lithium-ion battery.

The present invention has the following advantages:

Currently, the State of Charge (SOC) cannot be directly measured and can only be estimated. Common analysis methods include the coulomb counting method, open-circuit voltage method, impedance method, Kalman filtering, and neural network methods, among others. These methods may introduce errors into the final SOC estimation results due to inaccuracies in the measurement of certain parameters, leading to larger errors. At the same time, they may also result in unstable outcomes due to the high computational load. During the charging process of lithium-ion batteries, the density and elastic modulus of the electrodes change with the SOC. Ultrasonic non-destructive testing (NDT) offers characteristics such as high speed, non-contact, and high accuracy rate, and is sensitive to internal property changes of objects, allowing for the detection of local characteristics of the battery. By leveraging the changes in the internal electrodes of the lithium-ion battery that affect the propagation of ultrasonic waves, the reflective characteristics of the battery can be characterized, establishing a connection with the SOC, and enabling the detection of the local charge state of the lithium-ion battery.

### BRIEF DESCRIPTION OF THE SEVERAL VIEWS OF THE DRAWINGS

FIG. 1: A model of the 11-layer structure of a lithium-ion battery

FIG. 2: A schematic diagram of the experimental setup.

FIG. 3: An illustrative diagram of the angular fixture.

FIG. 4: A three-dimensional plot of the reflection coefficient angular spectrum under different states of charge, with the left peak value line defined by the function f(x)=−5.828e−05*x\hat{ }2+0.001282*x+13.92 and the right peak value line defined by the function f(x)=5.245e−05*x\hat{ }2−0.02661*x+23.37.

FIG. 5: The reflection coefficient angular spectrum at a specific State of Charge (SOC).

### MODES FOR CARRYING OUT THE INVENTION

The working principle of the present invention is as follows:

By utilizing ultrasonic water immersion detection, the invention involves detecting the ultrasonic reflection coefficients of a pouch lithium-ion battery under different states of charge, and by changing the angle between the ultrasonic transducers, obtaining the reflection coefficient angular spectrum of the lithium-ion battery under various states of charge (SOC) to characterize the battery's charge state.

Further detailed descriptions of the content of the present invention are provided below with reference to specific examples:

### EXAMPLE 1

The steps are as follows:

Step S1: Take a 0.7 mm lithium-ion pouch cell (laminated structure), and use an ultrasonic charging and discharging device to charge and discharge the laminated lithium-ion battery. Initially, discharge the lithium-ion battery to a cut-off voltage of 3V, then let it rest for 2 minutes, and charge it to a charging cut-off voltage of 4.2V.

Step S2: The total time T required to discharge the fully charged lithium-ion battery to 3V at a rate of 1 C is 50 minutes. The State of Charge (SOC) of the battery is calculated using the formula:

State of Charge(SOC)=(T−t)/T*100% SOC, where t is the discharge time, and t ranges from 0 to 50 minutes.

Step S3: With a time interval of 5 minutes, set the discharge times t to 0 minutes, 5 minutes, 10 minutes, 15 minutes, 20 minutes, 25 minutes, 30 minutes, 35 minutes, 40 minutes, 45 minutes, and 50 minutes, respectively. These correspond to lithium-ion battery states of charge of 100% SOC, 90% SOC, 80% SOC, 70% SOC, 60% SOC, 50% SOC, 40% SOC, 30% SOC, 20% SOC, 10% SOC, and 0% SOC.

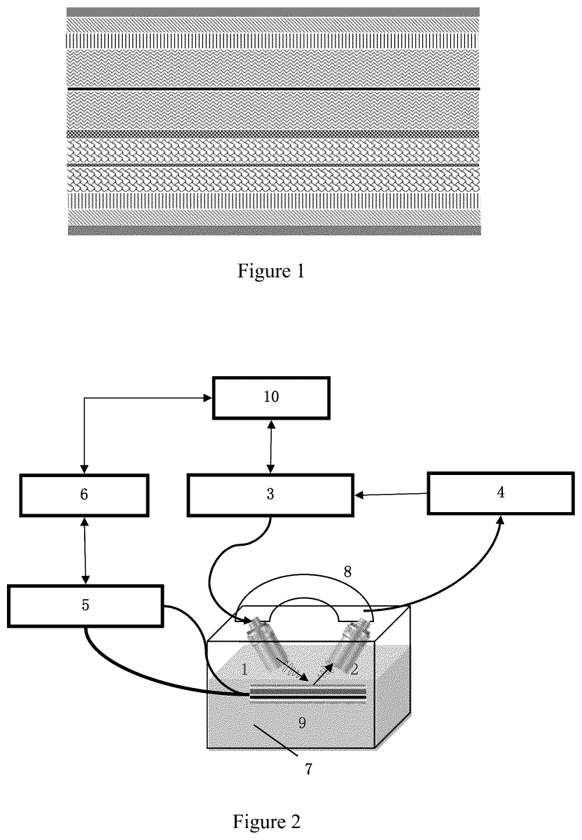

Step S4: Experimental apparatus design, to perform measurements of the ultrasonic reflection coefficient at variable angles, a measurement system for variable angle ultrasonic reflection coefficients is constructed. This system includes: two ultrasonic probes (1, 2), an embedded controller (3), a digital oscilloscope (4), a battery testing system (5), a middleware (6), a water tank (7), an angular fixture (8), a lithium-ion single-cell sample (9), and a computer (10). The connection method is as shown in FIG. 2. The two terminals of the lithium-ion battery under test are connected to the battery testing system (5), with waterproof treatment applied to the terminals, and then immersed in the water tank (7) along with the ultrasonic probes. The two ultrasonic probes (1, 2) are secured by the angular fixture (8), and the ultrasonic signal is emitted and received at a certain angle to measure the reflected signal. The embedded controller (3) is connected to the transmitting ultrasonic probe (1) to emit the ultrasonic signal, and the digital oscilloscope (4) is connected to the receiving ultrasonic probe (2) and also connected to the embedded controller (3) for signal processing and data acquisition. The battery testing system (5) monitors and controls the SOC of the lithium-ion battery in real-time, allowing for changes in the SOC of the lithium-ion battery. The computer is connected to the battery testing system via the middleware (6) for signal transmission.

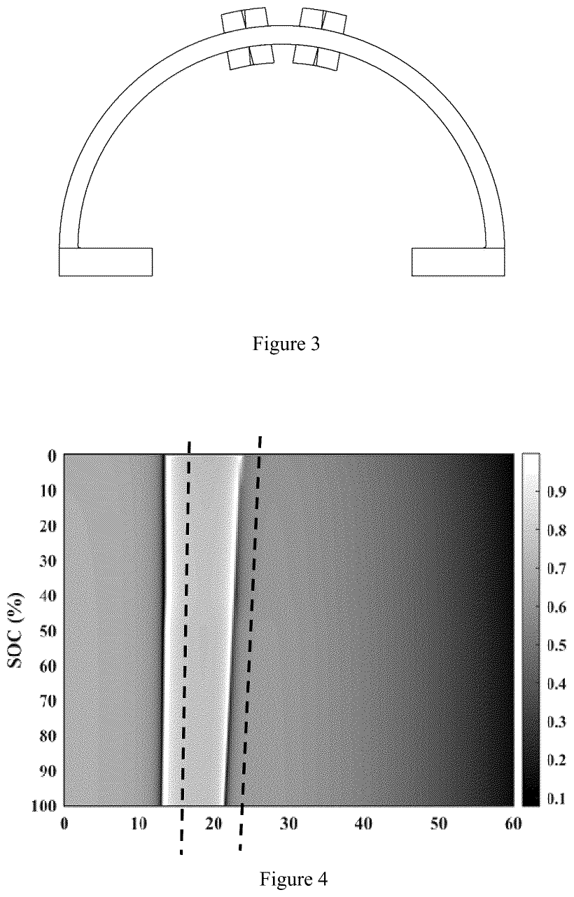

Step S5: The angular fixture allows for the ultrasonic transducers to emit and receive ultrasonic waves at different angles, which can be adjusted and fixed. As shown in FIG. 3, the angle can range from (0-60°).

Step S6: Select two ultrasonic probes with a central frequency of 1 MHz, fixed by the angular fixture, and vary the angle between the two ultrasonic probes from 0° to 60°. Start from 0° with a step size of 1°, and obtain a total of 61 reflection signals. Fit the reflection coefficients obtained from the Fourier transform to obtain the reflection coefficient angular spectrum curve for a certain SOC. Repeat this step until the reflection coefficient angular spectrum curves for the 11 states of charge of the lithium-ion battery from Step S3 are obtained.

Step S7: Plot the reflection coefficient angular spectrum at different SOCs, and fit the reflection coefficient angle curves obtained from the 11 different states of charge into a three-dimensional graph, as shown in FIG. 4. From the three-dimensional graph of the reflection coefficient angular spectrum obtained, the coordinates of the two peak points trace out two curve equations as follows:

$$F 1 ( x ) = 5.245 e - 05 * x \hat{} 2 - 0.02661 x + 23.37 ; ( Right peak , x represents the angle )$$

$$F 2 ( x ) = - 5.828 e - 05 * x \hat{} 2 - 0.001282 x + 13.92 ; ( Left peak , x represents the angle )$$

As the State of Charge (SOC) of the lithium-ion single cell increases, the second peak of the three-dimensional reflection coefficient angular spectrum shifts towards a smaller angle. By establishing the mapping relationship between the ultrasonic reflection coefficient angular spectrum and the SOC of the lithium-ion battery, the SOC of the lithium-ion battery is characterized.

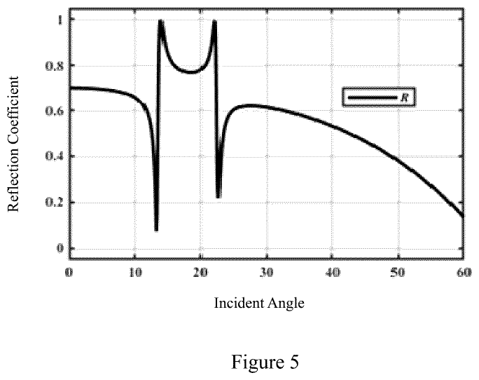

Step S8: Characterize the SOC of an unknown lithium-ion battery. The horizontal distance between the two peak value curves obtained in Step 7 represents the distance between the two peak points of the reflection coefficient angular spectrum at a certain SOC of the lithium-ion battery. By establishing the mapping relationship between the SOC of the lithium-ion battery and the reflection coefficient angular spectrum, the SOC of the lithium-ion battery is characterized. Charge the same type of lithium-ion battery using a charging and discharging device, and obtain the reflection coefficient angular spectrum curve of the lithium-ion battery at this SOC (FIG. 5) from Step 7. The variation curve of the reflection coefficient of the lithium-ion battery at this SOC is obtained, and the horizontal distance between the two peaks is calculated. By comparing the reflection coefficient angular spectra at different SOCs from the results of Step 7, the SOC of the tested lithium-ion battery is determined. It is determined that the SOC is 53.5% SOC upon comparison.

1. A method for detecting State of Charge (SOC) of lithium-ion batteries using an ultrasonic reflection coefficient, characterized by the following procedural steps:
Step 1: a lithium-ion battery is discharged to a cut-off voltage at room temperature using a constant current discharge device, then allowed to rest, after resting, the lithium-ion battery is charged to a charging cut-off voltage at room temperature using a constant current and constant voltage charging method;
Step 2: after resting, the lithium-ion battery is discharged to a discharge cut-off voltage at room temperature using a constant current discharging method; by varying discharge time, N lithium-ion batteries at different states of charge are obtained; the total discharge time T is the time taken for the lithium-ion battery to be discharged from the charging cut-off voltage to the discharge cut-off voltage; the state of charge of the lithium-ion battery is represented by the proportion of the discharge time t; the formula for calculating the state of charge is as follows:
$$State of Charge ( SOC ) = ( T - t ) / T * 100 \% SOC ;$$
Step 3: Detection device setup: construct an ultrasonic water immersion detection platform using an angular fixture that allows for the fixation of an angle between two ultrasonic probes;
Step 4: Employ the ultrasonic water immersion detection method, place a lithium-ion battery at a certain state of charge obtained from Step 2 into a water tank, and use a wideband ultrasonic probe with a certain center frequency in a one-actuation, one-reception mode to acquire the ultrasonic reflection signal from the lithium-ion battery;
Step 5: from Step 3, successively select the angles between the two ultrasonic probes from 0 to 60 degrees, and obtain the time-domain diagram of the ultrasonic reflection signal of the lithium-ion battery at each angle;
Step 6: process the time-domain reflection signals at different angles, and obtain the ultrasonic reflection coefficient of the lithium-ion battery at different incident angles through Fourier transformation;
Step 7: repeat Steps 4 to 6 until the ultrasonic reflection coefficient detection is completed for all the states of charge of the lithium-ion batteries obtained in Step 2;
Step 8: draw the reflection coefficient angular spectrum of the lithium-ion battery from 0% SOC to 100% SOC using all the reflection coefficients obtained from Step 7;
Step 9: analyze changes in the positions of the two peak values of the reflection coefficient angular spectrum, establish the mapping relationship between the reflection coefficient angular spectrum and the state of charge (SOC) of the lithium-ion battery, and use this to characterize the SOC of the lithium-ion battery;
the received reflection time-domain signals are processed to establish a three-dimensional reflection coefficient frequency spectrum, and the relationship between the positions of the two peak values in the spectrum is used to characterize the state of charge (SOC) of the pouch-type lithium-ion battery.

2. The method for detecting the State of Charge (SOC) of lithium-ion batteries using an ultrasonic reflection coefficient according to claim 1, wherein the central frequency of the experimental excitation is between 0.5 MHz and 1.5 MHz, and the angle between the two ultrasonic transducers is controlled and fixed by an angular fixture, with an adjustable range from 0° to 60°.
